(19) United States
(12) Patent Application Publication
(10) Pub. No.: US 2013/0032842 A1
(43) Pub. Date: Feb. 7, 2013

(54) LIGHT EMITTING DEVICE PACKAGE AND METHOD OF MANUFACTURING THE SAME

(71) Applicants: Jong Kil PARK, Suwon (KR); Sung Uk Zhang, Suwon (KR); Jong Sup Song, Suwon (KR)

(72) Inventors: Jong Kil PARK, Suwon (KR); Sung Uk Zhang, Suwon (KR); Jong Sup Song, Suwon (KR)

(21) Appl. No.: 13/563,227

(22) Filed: Jul. 31, 2012

(30) Foreign Application Priority Data
Aug. 1, 2011 (KR) 10-2011-0076720

(51) Int. Cl. H01L 33/60; H01L 33/48

(52) U.S. Cl. 257/98; 438/27; 257/E33.072

(57) ABSTRACT

There are provided a light emitting device package and a method of manufacturing the same. The light emitting device package includes a body part including a through hole formed in a thickness direction; at least one light emitting device disposed within the through hole; and a wavelength conversion part filling the through hole and supporting the light emitting device.

### CROSS-REFERENCE TO RELATED APPLICATIONS

This application claims the priority of Korean Patent Application No. 10-2011-0076720 filed on Aug. 1, 2011, in the Korean Intellectual Property Office, the disclosure of which is incorporated herein by reference.

### BACKGROUND OF THE INVENTION

1. Field of the Invention

The present invention relates to a light emitting device package and a method of manufacturing the same.

2. Description of the Related Art

In recent years, a light emitting diode (LED), emitting light according to the application of an electrical signal thereto, has been widely used as a light emitting source in various electronic products, as well as in mobile communications terminals, such as cell phones, personal digital assistants (PDAs), and the like.

This LED is a light emitting device capable of realizing light of various colors through an alternation of a compound semiconductor material, such as gallium arsenide (GaAs), aluminium gallium arsenide (AlGaAs), gallium nitride (GaN), InGaNP (indium gallium nitride phosphide), or the like.

Individual LEDs may emit red light, blue light, green light, or ultraviolet light, based on a composition contained therein, and red light, blue light, and green light emitted from the respective LEDs may be mixed to realize white light. However, such a method of realizing white light has disadvantages, such as the use of a plurality of LEDs and difficulties in realizing light of a uniform color.

Accordingly, a white LED is generally manufactured through the mixing of a fluorescent material for wavelength conversion with a resin, such as silicon, or the like, and the application of the mixture. By doing so, blue light, ultraviolet light, or the like, emitted from respective LEDs may be converted into white light, whereby only white light, monochromatic light, may be implemented.

However, such a method in which a fluorescent material is mixed with resin and then the mixture is applied, may have disadvantages, such as a non-uniform height of a wavelength conversion unit formed on a LED surface. In particular, in light emitting device packages manufactured through a mass production process, a wavelength conversion unit is formed through the injection of resin using a dispensing process to cover a LED disposed within a recess formed to be recessed at a predetermined depth. However, in this case, the amount of resin to be injected into the recess, and the density of a fluorescent material contained therein are not uniform, whereby defects, such as the individual packages having varying optical properties, may be generated.

### SUMMARY OF THE INVENTION

An aspect of the present invention provides a light emitting device package having a simple structure and allowing for a miniaturization thereof while maximizing heat radiation efficiency.

An aspect of the present invention also provides alight emitting device package having color coordinates exhibiting the same characteristics by uniformalizing a wavelength conversion unit in manufacturing the light emitting device package through a mass production.

According to an aspect of the present invention, there is provided a light emitting device package including: a body part including a through hole formed in a thickness direction; at least one light emitting device disposed within the through hole; and a wavelength conversion part filling the through hole and supporting the light emitting device.

The light emitting device may have a lower surface exposed from a lower surface of the body part to the outside.

The lower surface of the light emitting device may be coplanarly positioned with the lower surface of the body part.

The lower surface of the light emitting device may include electrode pads.

The through hole may include a reflection layer on a surface thereof so as to surround the light emitting device.

The through hole may include a projection portion or a prominence and depression portion, or a projection portion and a prominence and depression portion on a surface thereof.

The wavelength conversion part may include at least one fluorescent material and have a lower surface thereof positioned coplanarly with a lower surface of the body part.

The wavelength conversion part may have an upper surface and a lower surface respectively exposed from an upper surface and a lower surface of the body part.

According to another aspect of the present invention, there is provided a method of manufacturing a light emitting device package, the method including: preparing a body part including a plurality of through holes formed in a thickness direction on a vacuum tray including vacuum holes; mounting light emitting devices in the respective through holes; forming wavelength conversion parts by filling the respective through holes with a resin containing a fluorescent material so as to cover the light emitting devices; and separating the body part having the light emitting devices fixed into the respective through holes by the wavelength conversion parts, from the vacuum tray.

In the preparing of the body part, the plurality of through holes may be formed to correspond to locations of the vacuum holes so as to communicate between the through holes and the vacuum holes.

In the preparing of the body part, the plurality of through holes may be positioned to correspond to locations of the vacuum holes so as to communicate between the through holes and the vacuum holes.

In the mounting of the light emitting devices, the light emitting devices disposed within the through holes and placed on the vacuum tray may be fixed to the vacuum tray through the vacuum holes.

The light emitting devices may include electrode pads on lower surfaces thereof contacting the vacuum tray, and in the forming of the wavelength conversion parts, the resin may fill the respective through holes so as to cover surfaces of the light emitting devices, other than the lower surfaces thereof, including the electrode pads.

The forming of the wavelength conversion parts may include: planarizing the resin filling the respective through holes so as to be parallel with an upper surface of the body part; and curing the resin.

In the planarizing of the resin, an excess of the resin protruded upwardly from the upper surface of the body part in the respective through holes may be removed by a squeegee or the like.

The method may further include a polishing process performed on upper surfaces of the wavelength conversion parts.

The method may further include a dicing process performed along a cutting line such that individual light emitting device packages are separated.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A and 1B are diagrams schematically illustrating a light emitting device package according to an embodiment of the present invention;

FIG. 2A is a schematic diagram schematically illustrating a structure of a through hole from FIGS. 1A and 1B;

FIG. 2B is a diagram schematically illustrating another embodiment of the through hole of FIG. 2A;

FIG. 3 is a diagram schematically illustrating a state in which a reflection layer is provided on the through hole of FIG. 2A;

FIGS. 4A and 4B are diagrams schematically illustrating a state in which a plurality of light emitting devices are provided, from FIGS. 1A and 1B;

FIGS. 5A through 5C are diagrams schematically illustrating a light emitting device package according to another embodiment of the present invention;

FIG. 6 is a diagram schematically illustrating a lighting module on which the light emitting device package according to the embodiment of the present invention is mounted; and

FIGS. 7A and 7B through FIG. 15 are diagrams schematically illustrating respective processes in a method of manufacturing the light emitting device package according to an embodiment of the present invention.

### DETAILED DESCRIPTION OF THE INVENTION

A light emitting device package and a method of manufacturing the same according to embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and sizes of components are exaggerated for clarity. The same or equivalent elements are referred to by the same reference numerals throughout the specification.

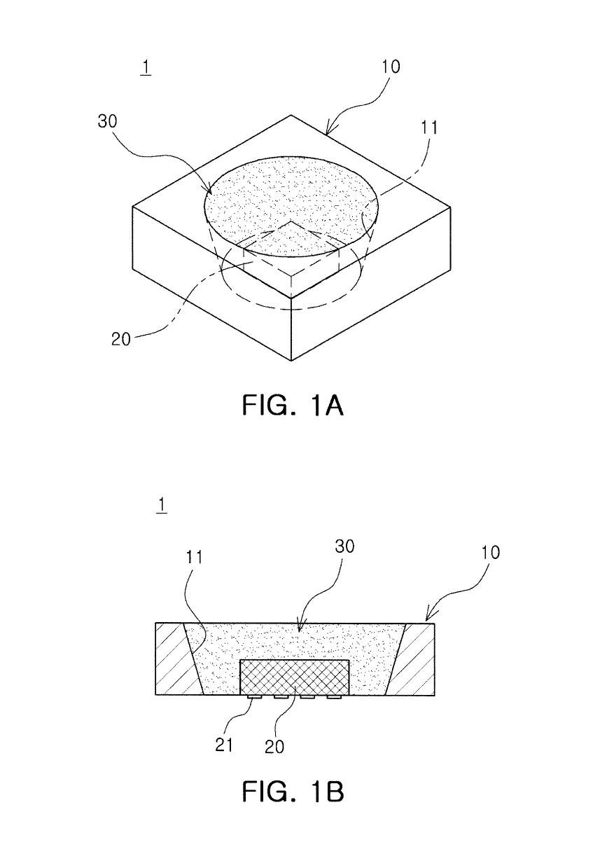

A light emitting device package according to an embodiment of the present invention will be explained with reference to FIGS. 1 through 4.

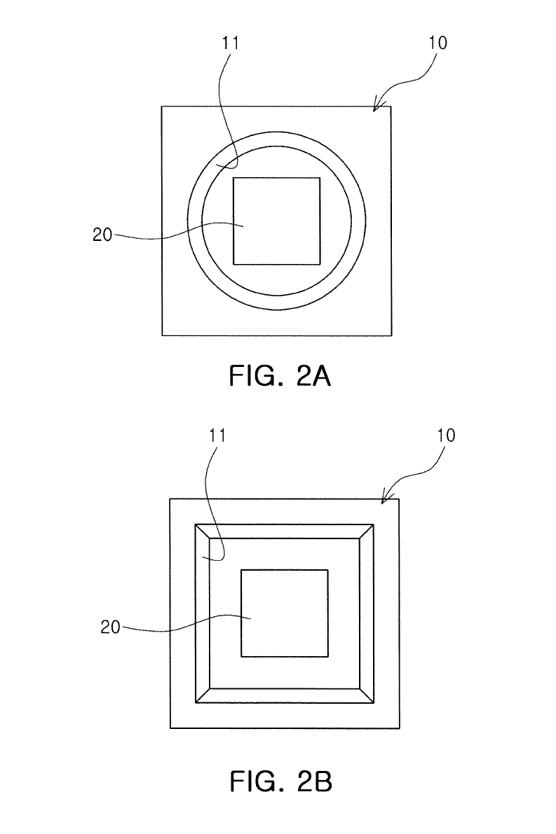

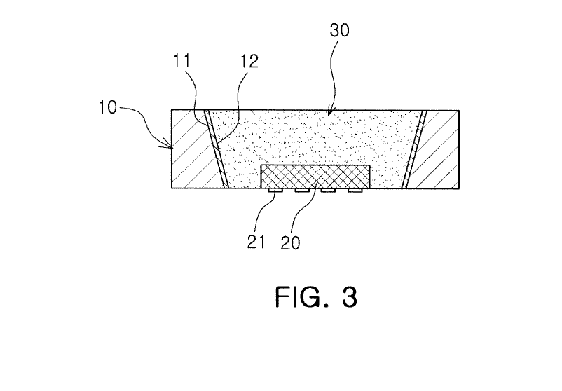

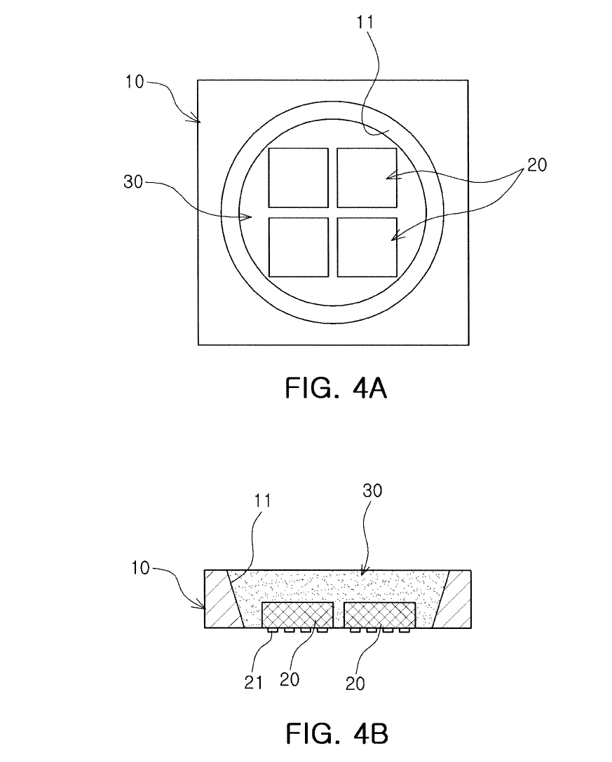

FIGS. 1A and 1B are diagrams schematically illustrating a light emitting device package according to an embodiment of the present invention. FIG. 2A is a schematic diagram schematically illustrating a structure of a through hole from FIGS. 1A and 1B. FIG. 2B is a diagram schematically illustrating another embodiment of the through hole of FIG. 2A. FIG. 3 is a diagram schematically illustrating a state in which a reflection layer is provided on the through hole of FIG. 2A. FIGS. 4A and 4B are diagrams schematically illustrating a state in which a plurality of light emitting devices are provided, from FIGS. 1A and 1B.

Referring to FIGS. 1A and 1B, a light emitting device package 1 according to an embodiment of the present invention may include a body part 10, a light emitting device 20, and a wavelength conversion part 30.

The body part 10 may include a through hole 11 penetrating therethrough in a thickness direction, that is, penetrating an upper surface and a lower surface thereof, and may reflect light generated by a light emitting device 20 while protecting the light emitting device 20 disposed within the through hole 11.

The body part 10 may be made of a white molding compound having high light reflectance, which may reflect light generated by the light emitting device 20 to allow for an increase in quantity of light emitted in an upward direction.

The white molding compound may include a thermosetting resin-based material or a silicon resin-based material having high heat resistance. In addition, a white pigment and filler, a hardening agent, a releasing agent, an antioxidant, an adhesion improver, or the like may be added to the thermosetting resin-based material.

The body part 10 may be made of a ceramic having superior heat resistance and abrasion resistance so as to minimize effects due to heat generated by the light emitting device 20.

The through hole 11 may be included in the center of the body part 10 and formed in the thickness direction so as to penetrate the upper surface and the lower surface of the body part 10. The through hole 11 may include an internal space accommodating the light emitting device 20 therein and have a tapered cup shape in which an inner surface thereof is inclined inwardly from the upper surface of the body part 10 to the lower surface thereof, so as to form an inverted truncated conical structure having an area of an upper portion greater than that of a lower portion on which the light emitting device 20 is disposed.

As depicted in FIG. 2A, the through hole 11 may have a circular shape. In addition, the through hole 11 may have a quadrangular shape corresponding to a shape of the light emitting device 20, as depicted in FIG. 2B. Alternatively, the through hole 11 may have a polygonal shape in consideration of light reflective properties.

As illustrated in FIG. 3, the through hole 11 may include a reflection layer 12 on the inner surface thereof so as to surround a circumference of the light emitting device 20. The reflection layer 12 may be made of a highly reflective metallic material and be attached in the form of a thin film or be formed by a method such as coating, deposition, or the like. Accordingly, a deformation of the surface of the through hole 11 due to high-temperature heat generated by the light emitting device 20 may be prevented.

The light emitting device 20 may be disposed at the bottom of the through hole 11, while not contacting the body part 10. The light emitting device 20 is a semiconductor device emitting light having a predetermined wavelength, according to an electrical signal applied from the outside, and may include an LED chip. The light emitting device 20 may emit blue light, red light, or green light according to a material contained therein, and may also emit white light.

The light emitting device 20 may have electrode pads 21 for receiving an electrical signal on the same surface, a lower surface thereof, and may include a bare chip having no wavelength conversion part formed on a surface thereof. The electrode pads 21 may be, for example, a plurality of P-type electrodes and n-type electrodes.

As in FIGS. 1A and 1B through FIGS. 2A and 2B, the light emitting device 20 may be disposed within the through hole 11 in such a manner that the lower surface thereof, including the electrode pads 21, may be exposed from the lower surface of the body part 10 to the outside. In addition, the light emitting device 20 may be disposed such that the exposed lower surface thereof is positioned coplanarly with the lower surface of the body part 10.

As in FIGS. 1A and 1B through FIG. 3, the light emitting device 20 may be singularly provided within the through hole 11. In addition, as depicted in FIGS. 4A and 4B, the light emitting device 20 may be provided in plural, and the plurality of light emitting devices 20 may be arranged in a matrix structure. In this case, the plurality of light emitting devices 20, arranged within the same through hole 11, may be homogeneous or heterogeneous.

The wavelength conversion part 30 may fill the through hole 11 and supportively fix the light emitting device 20 disposed within the through hole 11 to the body part 10, while not having contact with the body part 10. That is, the light emitting device 20, disposed within the through hole 11, may be supported by the wavelength conversion part 30 filling the through hole 11, to be fixed into the body part 10.

The wavelength conversion part 30 may convert a wavelength of light emitted from the light emitting device 20 into a light wavelength of a desired color. For example, the wavelength conversion part 30 may convert a single color light, such as red light or blue light into white light. To this end, resin forming the wavelength conversion part 30 may contain at least one fluorescent material. In addition, resin forming the wavelength conversion part 30 may also contain an ultraviolet ray absorbent material, absorbing ultraviolet light generated by the light emitting device 20.

The wavelength conversion part 30 may fill the through hole 11 to be cured. As the wavelength conversion part 30, resin having a high level of transparency, enabling light generated by the light emitting device 20 to penetrate therethrough with minimal loss may be selected, and, for example, an elastic resin may be used therefor. Since an elastic resin, a resin in the form of gel, such as silicon or the like, may rarely undergo a change in properties due to light of a single wavelength, for example, yellowing, while having a high refractive index, it has superior optical characteristics. In addition, since the elastic resin may maintain the form of a gel or an elastomer, even after a curing operation, the light emitting device may be more stably protected from stress due to heat, vibrations and external impacts. Furthermore, the through hole 11 may be filled with the wavelength conversion part 30 in a liquid state and then be cured, whereby internal bubbles in the curing operation may be exposed to be smoothly expelled to the outside.

The wavelength conversion part 30 may have an upper surface and a lower surface respectively exposed from the upper surface and the lower surface of the body part 10 to the outside through the through hole 11. In addition, the lower surface of the wavelength conversion part 30 may be positioned coplanarly with the lower surface of the body part 10. Thus, all of the lower surface of the body part 10, the lower surface of the wavelength conversion part 30, and the lower surface of the light emitting device may be coplanarly positioned with regard to one another.

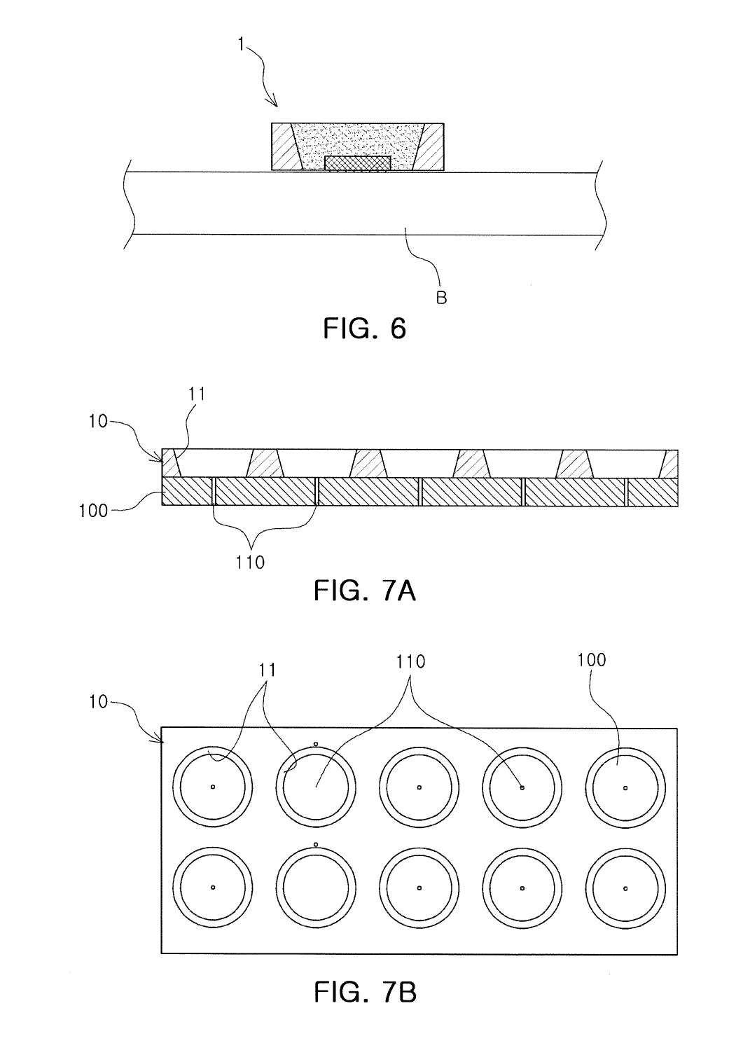

Through this structure, as depicted in FIG. 6, the light emitting device package 1 may be stably mounted on a substrate (B) of a product such as a lighting apparatus (not shown), and may be used as a light source.

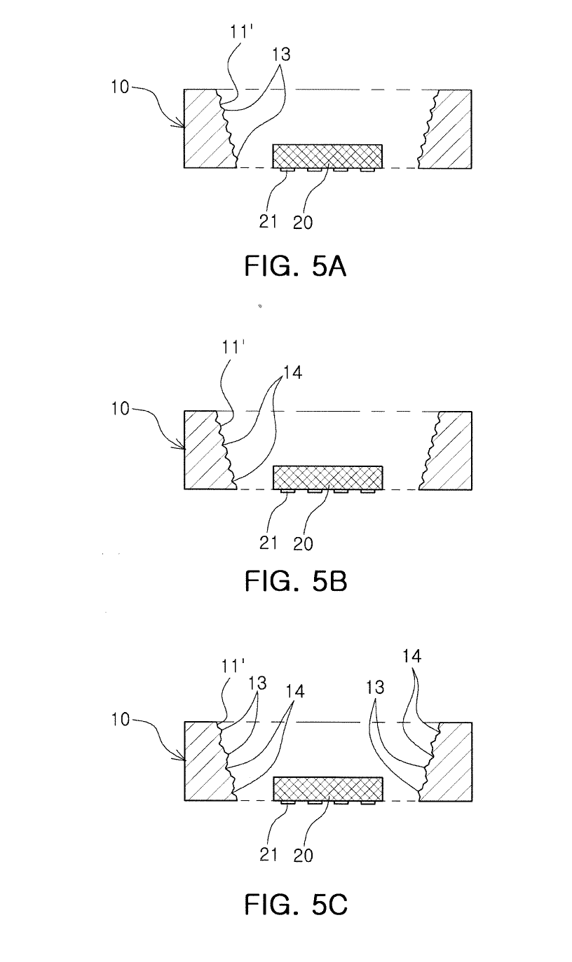

Referring to FIGS. 5A through 5C, a light emitting device package according to another embodiment of the present invention will be explained.

Components configuring the light emitting device package according to the embodiment illustrated in FIGS. 5A through 5C have substantially the same structures as those according to the foregoing embodiment illustrated in FIGS. 1A and 1B through FIGS. 4A and 4B. However, since a through hole structure of the body part is different from that of the foregoing embodiment illustrated in FIGS. 1A and 1B through FIGS. 4A and 4B, a description regarding elements overlapping with those of the foregoing embodiment may be omitted, a constitution of the through hole will be mainly discussed.

FIGS. 5A through 5C are diagrams schematically illustrating a light emitting device package according to another embodiment of the present invention.

As illustrated in FIG. 5A, a through hole 11′ may include projection portions 13 on a surface thereof. In addition, the through hole 11′ may include prominence and depression portions 14 as depicted in FIG. 5B. In addition, the through hole 11′ may include the projection portions 13 and the prominence and depression portions 14 as depicted in FIG. 5C.

Each of the projection portions 13 and the prominence and depression portions 14 may be provided in plural along the inner surface of the through hole 11′, and the plurality of projection portions 13 and the prominence and depression portions 14 may be protruded to have various sizes or may be recessed at various depths. Further, shapes of the projection portions 13 and the prominence and depression portions 14 may be uniformly formed or may be formed to have various shapes.

The projection portions 13 and the prominence and depression portions 14 may reflect light generated by the light emitting device 20 at various angles, such that light distribution may be variously controlled. Furthermore, the projection portions 13 and the prominence and depression portions 14 may increase coupling force between the wavelength conversion part 30 and the through hole′ 11, such that the wavelength conversion part 30 formed within the through hole 11′ may not be easily separated from an interface between the wavelength conversion part 30 and the through hole′ 11. Through this structure, combinational reliability between the body part 10 and the wavelength conversion part 30 may be secured.

Referring to FIGS. 7A and 7B through FIG. 15, a method of manufacturing the light emitting device package according to an embodiment of the present invention will be explained. FIGS. 7A and 7B through FIG. 15 are diagrams schematically illustrating respective processes in a method of manufacturing the light emitting device package according to an embodiment of the present invention.

As illustrated in FIGS. 7A and 7B, the body part 10 having the plurality of through holes 11 formed therein may be prepared on a vacuum tray 100, the plurality of through holes 11 penetrating the upper surface and the lower surface of the body part 10.

The vacuum tray 100, a plate structure made of a metallic material, may support the body part 10 and include a plurality of vacuum holes 110. The plurality of through holes 11 may be arranged in a matrix structure having rows and columns.

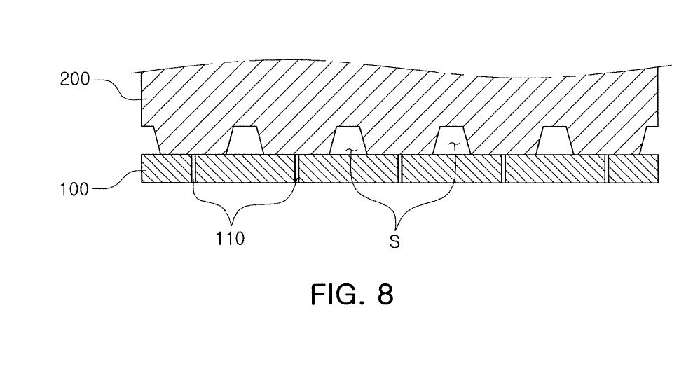

As illustrated in FIG. 8, the body part 10 may be prepared on the vacuum tray 100 in such a manner that a molding resin is injected between a mold 200 and the vacuum tray 100 to form the plurality of through holes 11 corresponding to locations of the plurality of vacuum holes 110 so as to communicate between the through holes 11 and the vacuum holes 110.

Specifically, the mold 200 having the through holes 11 may be disposed on the vacuum tray 100 in such a manner that the through holes 11 correspond to the locations of the respective vacuum holes 110. Moreover, the molding resin may be injected to fill a molding space S formed between the mold 200 and the vacuum tray 100 and then cured, such that the body part 10 may be formed on the vacuum tray 100.

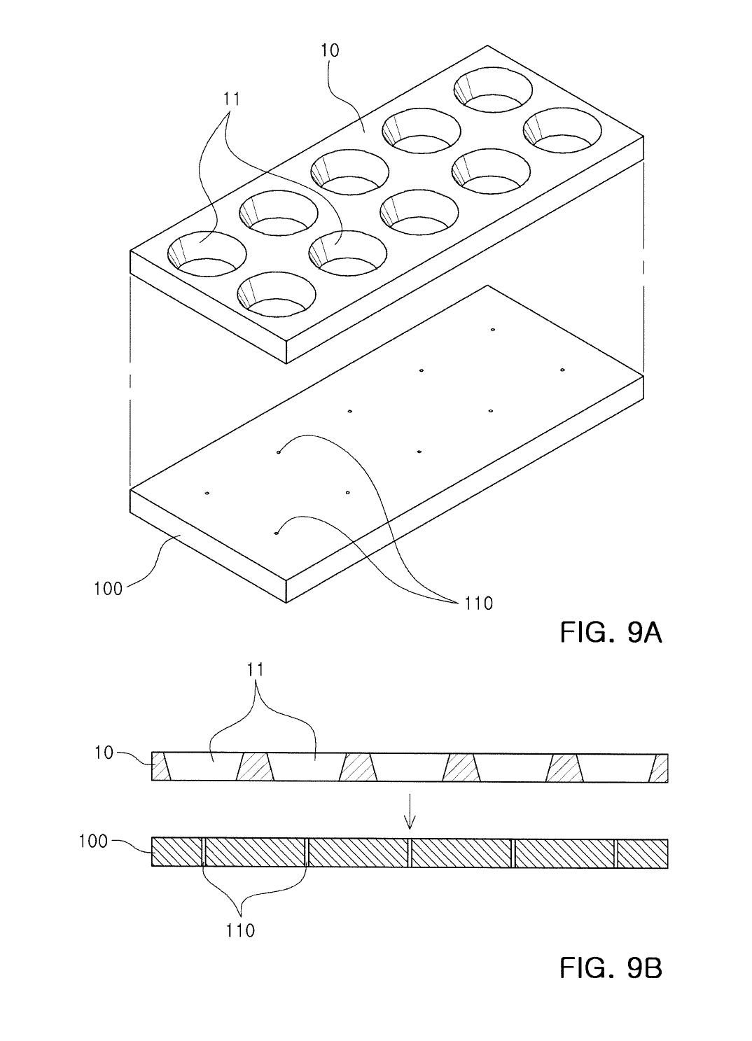

Meanwhile, as in FIGS. 9A and 9B, the body part 10 manufactured through a separate process may be attached to the vacuum tray 100. In this case, the body part 10 may be prepared on the vacuum tray 100 in such a manner that the plurality of through holes 11 are positioned to correspond to the locations of the plurality of vacuum holes 110 so as to communicate between the through holes 11 and the vacuum holes 110.

Meanwhile, the reflection layer 12 made of a highly reflective metallic material may be formed on a surface of each of the through holes 11. The reflection layer 12 may be attached in the form of a thin film or formed by a method such as coating, deposition, or the like.

In addition, the projection portions 13 or the prominence and depression portions 14, or the projection portions 13 and the prominence and depression portions 14 may be further formed on the inner surface of each through hole 11. Each of the projection portions 13 and the prominence and depression portions 14 may be provided in plural along the inner surface of each through hole 11, and the plurality of projection portions 13 and the prominence and depression portions 14 may be protruded to have various sizes or may be recessed at various depths.

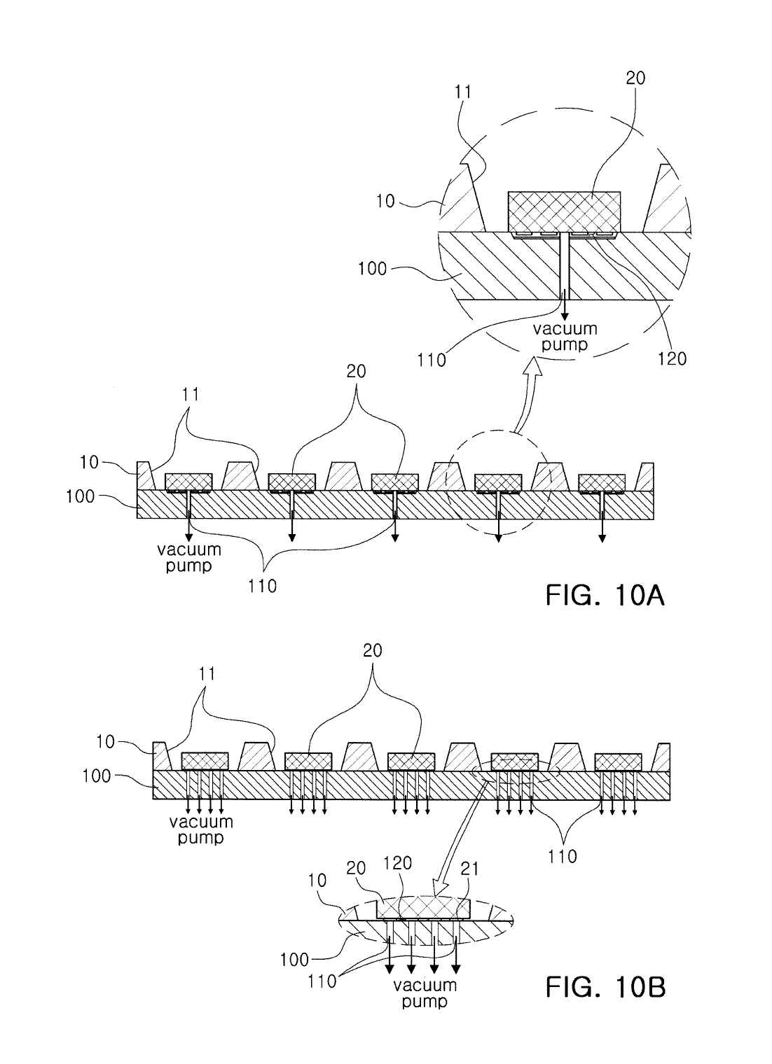

Next, as illustrated in FIGS. 10A and 10B, the plurality of light emitting devices 20 may be disposed within the respective through holes 11 of the body part 10. Each of the light emitting devices 20 may have the electrode pads 21 for receiving an electrical signal on the same surface, the lower surface thereof, and include a bare chip having no wavelength conversion part formed on a surface thereof. The electrode pads 21 may be, for example, a plurality of P-type electrodes and n-type electrodes.

The light emitting devices 20 may be disposed within the through holes 11 while not contacting the body part 10 in such a manner that lower surfaces thereof including the electrode pads 21 are placed on an upper surface of the vacuum tray 100. In this case, the upper surface of the vacuum tray 100 on which the light emitting devices 20 are placed, may have recesses 120 accommodating the electrode pads 20 and formed to be recessed at a predetermined depth.

Further, the light emitting devices 20 disposed within the through holes 11 and placed on the vacuum tray 100 may be fixed to the vacuum tray 100 through the vacuum holes 110. By doing so, the light emitting devices 20 are stably fixed into the respective through holes 11 while not being transferred, in the manufacturing processes.

The vacuum holes 110 may be connected to vacuum pumps (not shown) and allow for the fixation of the light emitting devices 20 through vacuum suction generated due to the operation of the vacuum pumps.

Each of the plurality of vacuum holes 110 may be connected to each through hole 11 as depicted in FIG. 10A. Alternatively, the plurality of vacuum holes 110 may be connected to each through hole 11 as depicted in FIG. 10B. In this case, the plurality of vacuum holes 110 may be positioned to correspond to the respective electrode pads 21 of each light emitting device 20.

The light emitting device 20 may be singularly provided or may be provided in plural within each through hole 11.

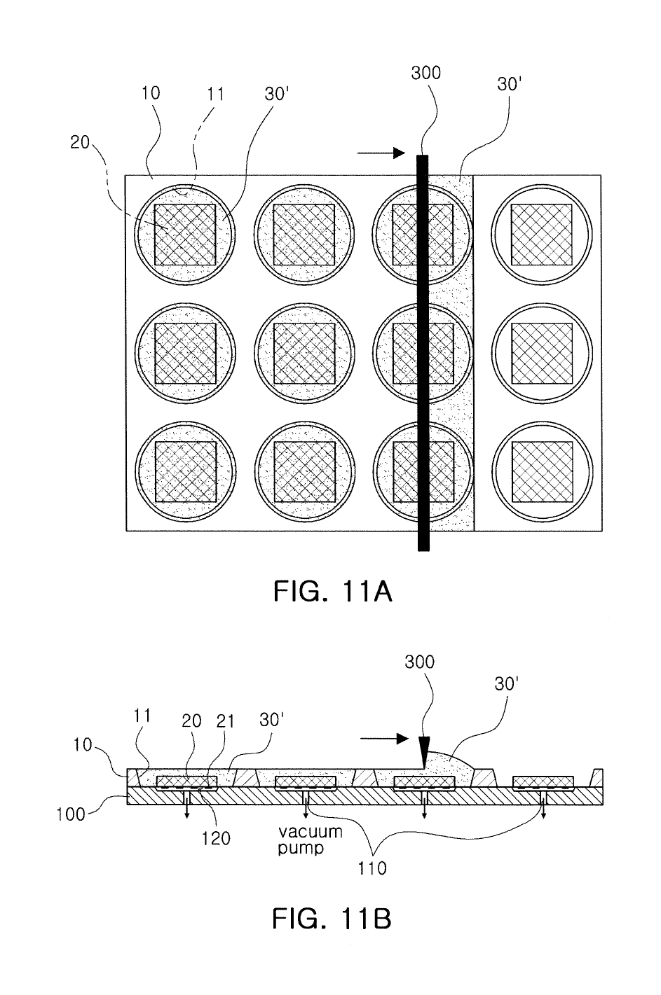

Then, as illustrated in FIGS. 11A and 11B, in order to cover the light emitting devices 20, a resin 30′, containing a fluorescent material, may fill the respective through holes 11 to form the wavelength conversion parts 30.

Specifically, a certain amount of the resin 30′, containing a fluorescent material, may be injected onto an upper surface of the body part 10 by using a dispenser (not shown) or the like. An amount of the resin 30′, sufficient to fill the plurality of through holes 11 formed in the body part 10, may be injected thereinto. The injected resin 30′ may be spread from one end of the body part 10 to the other end opposed thereto by using a squeegee 300 or the like to fill the respective through holes 11 in a printing scheme. The resin 30′ may fill the respective through holes 11 so as to cover side surfaces and upper surfaces of the light emitting devices 20, other than the lower surfaces thereof, having the electrode pads 21.

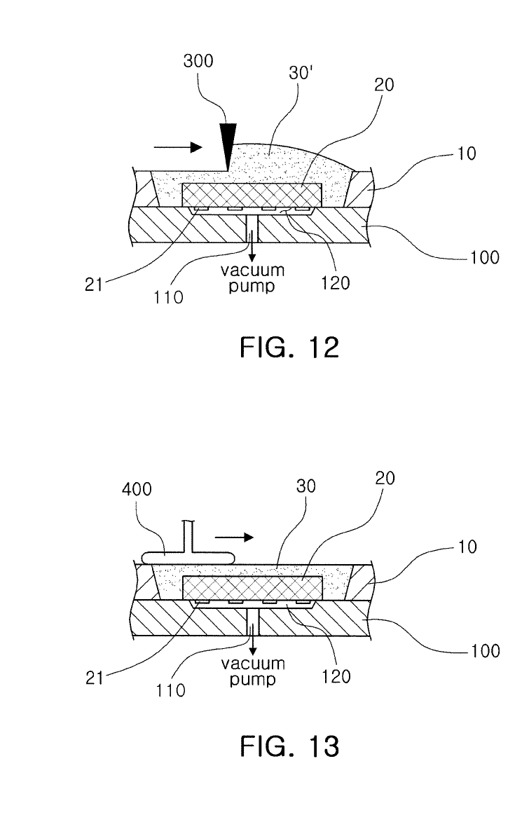

In addition, as illustrated in FIG. 12, an excess of the resin 30′ protruded upwardly from the upper surface of the body part 10 in the respective through holes 11 may be removed through the squeegee 300 or the like, such that the resin 30′, filling the respective through holes 11, may be planarized so as to be parallel with the upper surface of the body part 10.

Next, the resin 30′ is cured to form the wavelength conversion parts 30. Thus, the wavelength conversion parts 30 formed in the respective through holes 11 may have a uniform height and uniform density.

By using the printing scheme as above, the plurality of through holes may be filled with resin containing a fluorescent material at the same time through a single process, whereby processing time may be reduced. The wavelength conversion parts having entirely the same characteristics may be formed at the same time to allow for an increase in production yield.

The wavelength conversion parts 30 may convert a wavelength of light emitted from the light emitting devices 20 into a desired color wavelength. For example, the wavelength conversion parts 30 may convert light of a single color, such as red light or blue light into white light. To this end, a resin forming the wavelength conversion parts 30 may contain at least one fluorescent material. In addition, resin forming the wavelength conversion parts 30 may also contain an ultraviolet ray absorbent material absorbing ultraviolet light generated by the light emitting devices 20.

The wavelength conversion parts 30 may fill the through holes 11 to be cured. As the wavelength conversion parts 30, resin having a high level of transparency, enabling light generated by the light emitting devices 20 to penetrate therethrough with a minimal loss may be selected, and, for example, an elastic resin may be used therefor. Since the elastic resin, resin in the form of a gel, such as silicon or the like, may rarely undergo a change due to light of a single wavelength, for example, yellowing, while having a high refractive index, it has superior optical characteristics. In addition, since an elastic resin may maintain the form of a gel or an elastomer even after a curing operation, the light emitting devices may be more stably protected from stress due to heat, vibrations and external impacts. Furthermore, the through holes 11 may be filled with the wavelength conversion parts 30 in a liquid state and then be cured, whereby internal bubbles in the curing operation may be exposed to be smoothly expelled to the outside.

Meanwhile, as illustrated in FIG. 13, after the wavelength conversion parts 30 are formed in the respective through holes 11 to be cured, a polishing process may be further performed on the cured wavelength conversion parts 30 using a polishing apparatus 400. By doing so, a part of the resin remaining on the upper surface of the body part 10 may be entirely removed therefrom.

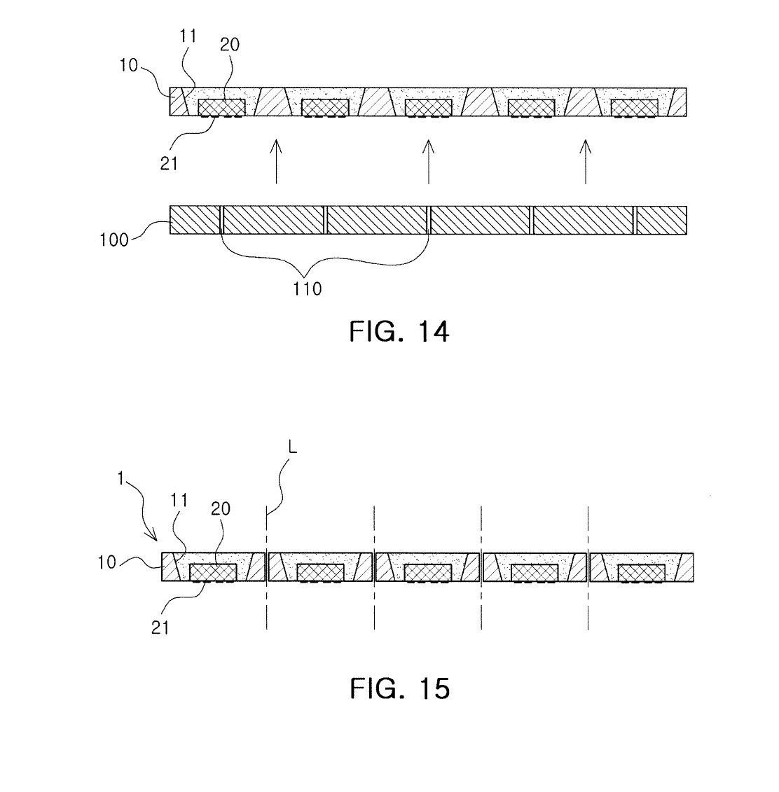

Next, as illustrated in FIG. 14, the body part 10 having the light emitting devices 20 fixed into the through holes 11 by the wavelength conversion parts 30 may be separated from the vacuum tray 100.

The lower surface of the body part 10 and lower surfaces of the wavelength conversion parts 30 coming into contact with the upper surface of the vacuum tray 100 may be exposed to the outside through the separation between the body part 10 and the vacuum tray 100. Also, the lower surfaces of the light emitting devices 20 fixed into the through holes 11 by the wavelength conversion parts 30 may be exposed to the outside. In this case, all of the lower surface of the body part 10, the lower surfaces of the wavelength conversion parts 30, and the lower surfaces of the light emitting devices 20 may be coplanarly positioned with respect to one another.

Next, as illustrated in FIG. 15, a dicing process may be performed along a cutting line (L), such that individual light emitting device packages are separated to thereby mass-manufacture the plurality of light emitting device packages 1.

In the plurality of light emitting device packages 1 mass-manufactured as above, the wavelength conversion parts 30 may have a uniform thickness (or height), such that light emitting device packages having the same optical characteristics may be mass-manufactured. Therefore, a defect rate may be minimized to allow for an increase in production yield.

As set forth above, according to embodiments of the invention, alight emitting device could be exposed from a lower portion of a package body and directly mounted on a substrate, whereby heat generated during an operation of the light emitting device could be directly emitted to the substrate to allow for a maximization in heat radiation efficiency.

In addition, the light emitting device may not be mounted on the body to allow for a miniaturization of a light emitting device package.

In addition, in manufacturing light emitting device packages having wavelength conversion parts formed therein through a mass production process, heights of the wavelength conversion parts may be uniformalized, such that a mass production of light emitting device packages having color coordinates exhibiting the same characteristics could be facilitated.

While the present invention has been shown and described in connection with the embodiments, it will be apparent to those skilled in the art that modifications and variations can be made without departing from the spirit and scope of the invention as defined by the appended claims.

What is claimed is:

1. A light emitting device package, comprising:
a body part including a through hole formed in a thickness direction;
at least one light emitting device disposed within the through hole; and
a wavelength conversion part filling the through hole and supporting the light emitting device.

2. The light emitting device package of claim 1, wherein the light emitting device has a lower surface exposed from a lower surface of the body part to the outside.

3. The light emitting device package of claim 1, wherein a lower surface of the light emitting device is coplanarly positioned with a lower surface of the body part.

4. The light emitting device package of claim 1, wherein a lower surface of the light emitting device includes electrode pads.

5. The light emitting device package of claim 1, wherein the through hole includes a reflection layer on a surface thereof so as to surround the light emitting device.

6. The light emitting device package of claim 1, wherein the through hole includes a projection portion or a prominence and depression portion, or a projection portion and a prominence and depression portion on a surface thereof.

7. The light emitting device package of claim 1, wherein the wavelength conversion part includes at least one fluorescent material and has a lower surface thereof positioned coplanarly with a lower surface of the body part.

8. The light emitting device package of claim 1, wherein the wavelength conversion part has an upper surface and a lower surface respectively exposed from an upper surface and a lower surface of the body part.

9. A method of manufacturing a light emitting device package, the method comprising:
preparing a body part including a plurality of through holes formed in a thickness direction on a vacuum tray including vacuum holes;
mounting light emitting devices in the respective through holes;
forming wavelength conversion parts by filling the respective through holes with a resin containing a fluorescent material so as to cover the light emitting devices; and
separating the body part having the light emitting devices fixed into the respective through holes by the wavelength conversion parts, from the vacuum tray.

10. The method of claim 9, wherein in the preparing of the body part, the plurality of through holes are formed to correspond to locations of the vacuum holes so as to communicate between the through holes and the vacuum holes.

11. The method of claim 9, wherein in the preparing of the body part, the plurality of through holes are positioned to correspond to locations of the vacuum holes so as to communicate between the through holes and the vacuum holes.

12. The method of claim 9, wherein in the mounting of the light emitting devices, the light emitting devices disposed within the through holes and placed on the vacuum tray are fixed to the vacuum tray through the vacuum holes.

13. The method of claim 9, wherein the light emitting devices include electrode pads on lower surfaces thereof contacting the vacuum tray, and in the forming of the wavelength conversion parts, the resin fills the respective through holes so as to cover surfaces of the light emitting devices, other than the lower surfaces thereof, including the electrode pads.

14. The method of claim 9, wherein the forming of the wavelength conversion parts includes:
planarizing the resin filling the respective through holes so as to be parallel with an upper surface of the body part; and
curing the resin.

15. The method of claim 14, wherein in the planarizing of the resin, an excess of the resin protruded upwardly from the upper surface of the body part in the respective through holes is removed by a squeegee or the like.

16. The method of claim 14, further comprising a polishing process performed on upper surfaces of the wavelength conversion parts.

17. The method of claim 9, further comprising a dicing process performed along a cutting line such that individual light emitting device packages are separated.
